(19) United States
(12) Patent Application Publication
(10) Pub. No.: US 2025/0250159 A1
(43) Pub. Date: Aug. 7, 2025

(54) Reliable and Robust Zero Power Micro-Mechanical Switch

(71) Applicant: Zepsor Technologies, Inc., Burlington, MA (US)

(72) Inventor: Zhenyun QIAN, Lexington, MA (US)

(21) Appl. No.: 19/046,736

(22) Filed: Feb. 6, 2025

Related U.S. Application Data
(60) Provisional application No. 63/550,159, filed on Feb. 6, 2024.

(51) Int. Cl. B81B 3/00; B81C 1/00

(52) U.S. Cl. CPC B81B 3/0051; B81C 1/00976; B81B 2201/018; B81B 2201/045; B81B 2203/0118; B81B 2203/0315; B81B 2203/0361; B81C 2201/0104; B81C 2201/0111; B81C 2201/0132

(57) ABSTRACT

Robust and reliable microelectromechanical photoswitch devices are provided. The devices are better able to withstand mechanical shock and rough handling during transportation or field operation due to the use of a mechanical stop structure that limits displacement of movable parts of the devices and prevents their contacts from becoming locked. The technology also greatly extends the dynamic range of the sensors, enabling them to detect weak electromagnetic radiation signals as well as much stronger signals without damage when exposed to signals that are orders of magnitude larger than threshold.

### CROSS REFERENCE TO RELATED APPLICATIONS

This application claims the priority of U.S. Provisional Application No. 63/550,159, filed 6 Feb. 2024 and entitled “Reliable and Robust Zero Power Micro-Mechanical Switch”, the whole of which is hereby incorporated by reference.

### STATEMENT REGARDING FEDERALLY SPONSORED RESEARCH OR DEVELOPMENT

This invention was made with government support under Grant Nos. W912CG23C0016 awarded by the Defense Advanced Research Projects Agency (DARPA), 2304549 awarded by the National Science Foundation, and DE-AR0001607 awarded by the Department of Energy. The government has certain rights in the invention.

### BACKGROUND

Billions of batteries are used every year for occupancy sensors, cameras, touchless faucets, auto dispensers, smart door locks, thermostats, wearables and more. The frequent replacement of these batteries not only creates hassles for the users, but also is a waste of resources and leads to environmental issues. A prevalent problem is the continuous drain of power by the sensing components in battery-powered devices. For example, IR sensors have been widely used for presence or proximity detection in a variety of smart home devices and building automation products, and conventional IR sensors waste battery energy.

### SUMMARY

The present technology provides a microelectromechanical systems (MEMS) based IR sensor that consumes near-zero power in standby. The zero-power IR sensors (ZIR sensors) of the present technology can be chip-scale and lens-less with high performance and low cost of manufacture. They can be used by designers and engineers, for example, to build products for automation, smart home products, and automated hygiene products and plumbing fixtures which have battery life extended by at least 10-fold, and offer improved end users experience.

An aspect of the present technology is a micromechanical photoswitch (MP), which is a small (for example, covering an area of less than 1 mm²), highly sensitive mechanical relay that is sensitive to specific wavelengths of infrared (IR) radiation. The sensor is off-but-alert, such that it does not drain any battery power to continuously monitor the environment, yet is still capable of detecting and discriminating the IR radiation emitted by, for example, a human body, such as a hand, by using only the tiny amount of detected thermal energy in emitted IR radiation to close the contact of the MP, thereby triggering the device to, for example, turn on a valve, pump, screen, camera, or light.

The present application provides improved mechanical reliability compared to previous ZIR sensors. It is inherently a challenge for delicate MEMS devices to withstand mechanical shock that can be caused by rough handling, transportation, or field operation, because their operation relies on tiny movable parts. Shock can cause failure in MPs due to excessive displacement and stuck contacts. The present ZIR sensors address the challenges associated with shock and drop without any compromise in device performance. Furthermore, the technology also greatly extends the dynamic range of the sensors, meaning that they not only can detect small signals at threshold levels but also function properly when exposed to signals that are orders of magnitude larger than threshold.

One aspect of the invention is a

Another aspect of the invention is a

The technology can be further summarized in the following listing of features.
1. A microelectromechanical photoswitch comprising:
   a substrate;
   a first electrical contact;
   a maximum deflection limiter (MDL) attached to the surface of the substrate;
   a first cantilever attached to the substrate, the first cantilever comprising:
      an absorber head, wherein the absorber head comprises a second electrical contact disposed at a free end of the cantilever for movement into and out of electrical connection with the first electrical contact, and wherein the absorber head further comprises a plasmonic absorber that absorbs electromagnetic radiation within a spectral band selected for detection, the absorption of such electromagnetic radiation causing the second contact element to move toward the first contact element;
      an inner pair of temperature-sensitive bimaterial legs, and an outer pair of temperature-sensitive bimaterial legs, the inner pair of legs attached to opposite sides of the absorber head, the outer pair of legs attached to the surface of the substrate and disposed adjacent to the inner pair of legs forming two sets of inner and outer legs, the two sets of legs disposed symmetrically on opposite sides of the absorber head; and
      a first thermal isolation region connecting the inner and outer legs of the first set of legs, and a second thermal isolation region connecting the inner and outer legs of the second set of legs;
   wherein the first and second electrical contacts are separated by a gap when the photoswitch is in an open state;
   wherein absorption of said electromagnetic radiation by the plasmonic absorber causes the first electrical contact element and the second electrical contact element to form an electrical connection, thereby placing the photoswitch into a closed state; and
   wherein the MDL is configured to limit movement of the absorber head in direction of the substrate, thereby inhibiting formation of a stuck state of the photosensor.
2. The microelectromechanical photoswitch of feature 1, further comprising:
   a second cantilever disposed on the substrate adjacent to the first cantilever and with mirror symmetry to the first cantilever, the second cantilever comprising:
      a second head;
      an inner pair of temperature-sensitive bimaterial legs, and an outer pair of temperature-sensitive bimaterial legs, the inner pair of legs attached to opposite sides of the second head, the outer pair of legs attached to the surface of the substrate and disposed adjacent to the inner pair of legs forming first and second sets of inner and outer legs, the first and second sets of legs disposed symmetrically on opposite sides of the second head; and
      a first thermal isolation region connecting the inner and outer legs of the first set of legs, and a second thermal isolation region connecting the inner and outer legs of the second set of legs; and an additional MDL, wherein the additional MDL is configured to limit movement of the second head in direction of the substrate.
   3. The microelectromechanical photoswitch of feature 2, wherein the second head reflects electromagnetic radiation over a bandwidth that includes the selected spectral band and does not absorb electromagnetic radiation.
4. The microelectromechanical photoswitch of any of the preceding features, wherein the MDL is attached to the surface of the substrate below the absorber head.
5. The microelectromechanical photoswitch of feature 4, wherein the MDL is attached to the surface of the substrate below a perimeter zone of the absorber head.
6. The microelectromechanical photoswitch of any of the preceding features, comprising two or more MDLs, each attached to the surface of the substrate below the absorber head.
7. The microelectromechanical photoswitch of feature 2, wherein the additional MDL is attached to the surface of the substrate below the second head.
8. The microelectromechanical photoswitch of feature 2, wherein the additional MDL is attached to the surface of the substrate below a perimeter zone of the second head.
9. The microelectromechanical photoswitch of feature 2, comprising two or more additional MDLs, each attached to the surface of the substrate below the second head.
10. The microelectromechanical photoswitch of any of the preceding features, wherein the MDL has a form selected from the group consisting of columns having any geometrical shape in cross-section, truncated pyramids, and cuboids.
11. The microelectromechanical photoswitch of any of the preceding features, wherein the MDL has a cross-sectional diameter from about 1 μm to about 250 μm.
12. The microelectromechanical photoswitch of any of the preceding features, wherein the MDL has a height above the substrate from about 10 μm to about 750 μm.
13. The microelectromechanical photoswitch of any of the preceding features, comprising a gap between an upper surface of the MDL and a lower surface of the absorber head, the gap having a size from about 1 μm to about 150 μm in a resting state.
14. The microelectromechanical photoswitch of any of the preceding features, wherein the MDL comprises a material selected from the group consisting of silicon, silicon dioxide, copper, gold, aluminum, platinum, silver, tungsten, and metal oxides.
15. The microelectromechanical photoswitch of any of the preceding features, wherein the MDL is fabricated by a process comprising through silicon via fabrication.
16. The microelectromechanical photoswitch of any of the preceding features, wherein the MDL is fabricated by a process comprising bulk machining of the substrate.
17. The microelectromechanical photoswitch of any of the preceding features, wherein the photoswitch has an increased maximum power absorption of electromagnetic radiation compared to a similar device lacking the MDL.
18. The microelectromechanical photoswitch of any of the preceding features, wherein the photoswitch has a reduced likelihood of developing stuck contacts compared to a similar device lacking the MDL.
19. The microelectromechanical photoswitch of feature 18, wherein the photoswitch has a reduced likelihood of developing stuck contacts from mechanical shock or exposure to electromagnetic radiation of excessive power compared to a similar device lacking the MDL.
20. The microelectromechanical photoswitch of any of the preceding features, where in the selected spectral band is an infrared radiation.
21. The microelectromechanical photoswitch of any of the preceding features, which is vacuum packaged.
22. The microelectromechanical photoswitch of any of the preceding features, wherein the MDL comprises a heat conducting material.
23. An electronic circuit comprising the microelectromechanical photoswitch of any of the preceding features, a battery, and a transmitter or alarm.
24. An electrical device or a system comprising one or more microelectromechanical photoswitches of any of the preceding features.

The following patents and patent applications: describe related technology and are hereby incorporated by reference in their entireties: U.S. Pat. Nos. 10,643,810; 12,169,145; and 12,055,438.

### BRIEF DESCRIPTION OF THE DRAWINGS

FIGS. 1A-1C show aspects of an MP. FIG. 1A shows an embodiment of a system including the MP for detection of an IR source, such as the presence of a human or animal. FIG. 1B shows the component parts of an MP device. FIG. 1C shows how absorption of IR radiation leads to temperature changes within the device, with a resulting conformational change.

FIG. 2 is a schematic illustration of an MP device contact, showing the contact in open, closed, stuck closed, and stuck open conditions.

FIG. 3A shows a simulated response of an MP to shock. In previous designs, downwards displacements >50 μm cause the contact tip to become stuck. Upwards displacement does not lead to stuck or damaged contacts, due to the larger absorber head displacement. FIG. 3B shows a simulation of maximum stress vs. displacement. The upwards limit is 100 μm due to typical cavity depth in the lid wafer. Cavity depth in the substrate of previous MPs is about 190 μm, larger than the shock response.

FIG. 4A shows a cross-sectional view of a vacuum packaged MP device including the maximum deflection limiter (MDL) structure of the present technology. The MDL limits the downwards displacement to a few microns, within the material yield limit. FIG. 4B shows a top view of an MP showing the exemplary locations of the MDL structure. The MDLs are preferably placed along the horizontal center line of the device. The location along the x-axis can be determined based on the selected maximum allowable downwards displacement for each head. FIG. 4C shows another top view of an MP showing a preferred zone for placement of MDL structures beneath the head structures.

FIG. 5A shows a fabrication process for an MDL using a silicon through via (STV) process (Steps 1-5). Step 6 is an optional step of depositing amorphous silicon (a-Si) to define the distance between pillar and device head. FIG. 5B shows a different fabrication process for an MDL using bulk machining techniques.

FIGS. 6A-6B show how changing the shape of the thermal isolation link from 90-degree sharp turns to a round shape effectively reduces stress accumulation when the device is subject to the same displacement.

### DETAILED DESCRIPTION

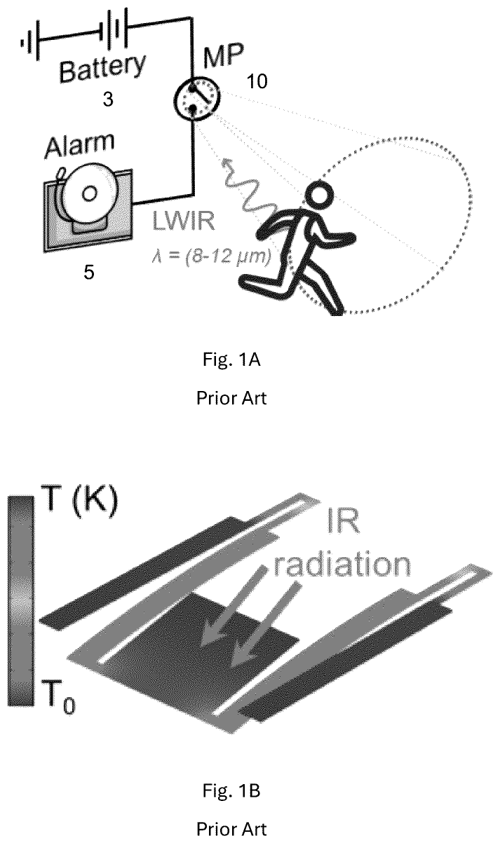

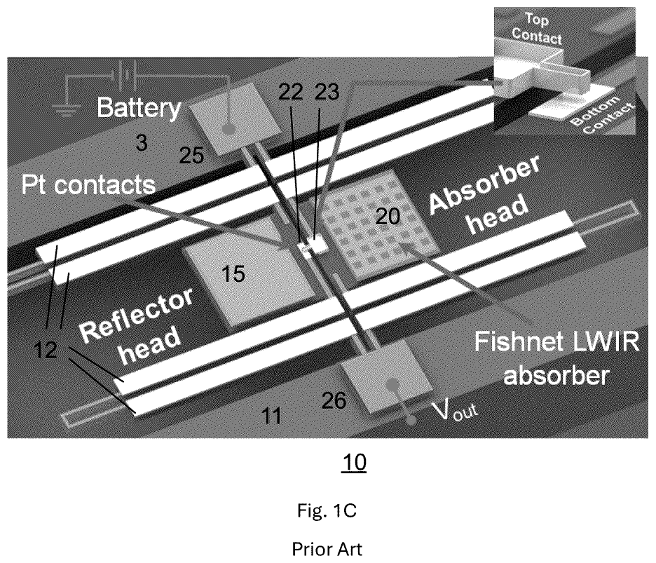

Micromechanical photoswitches (MPs), including zero power infrared (ZIR) sensors, can be employed in a variety of applications such as detecting IR or other electromagnetic radiation sources in an environment. In the embodiment depicted in FIG. 1A, ZIR 10 serves as a switch connecting battery 3 to load 5, such as an alarm; alternatively, the switch could activate a transmitter, or change the state of an RFID tag, for example. An earlier generation ZIR sensor is shown in FIG. 1B (see also U.S. Pat. No. 10,643,810). The ZIR sensor 10 can include the following components: (i) substrate 11; (ii) 4 pairs of identical bimorphs 12 that bend down in response to a temperature rise, caused by IR absorbed by the device; (iii) a reflector head 15 and an absorber head 20 having a spectrally selective absorber for electromagnetic radiation (such as IR); and (iv) a pair of metal contacts (22, 23) at each end of the heads that touch (close the switch) when the bending exceeds the gap between the contacts. The device is connected to a circuit, including battery 3, via metal pads 25 and 26. This happens when the input IR power is greater than the designed detection threshold; otherwise the contacts remain open.

The devices of the present technology are a type of microelectromechanical systems (MEMS) technology. Their component parts are generally in the micrometer range, or nanometer range, in size. They are different from, in structure and function, and not to be confused with, larger scale mechanical devices having components larger than the micrometer range and made using entirely different techniques, generally produced using the human eye without magnification.

The present technology improves the mechanical shock resistance and dynamic range of a class of devices described in U.S. Pat. No. 10,643,810. Those devices, which are microelectromechanical sensors or relays, form a key element of the present technology. In some embodiments, the sensor is a plasmonically activated by impinging electromagnetic radiation within a specific spectral wavelength band. The absorbed power is used to create a conducting channel between two bottom contacting metals (source and drain) and a top metal tip. The sensor contains two symmetrical, released cantilevers facing each other. Each cantilever includes a head (first head or absorber head), an inner, thermally sensitive pair of bimaterial legs, an outer temperature and stress compensating pair of bimaterial legs connected to the substrate; and a pair of thermal isolation regions between the bimaterial legs. The head of the second cantilever (second head or reflector) can be composed of a metal-insulator-metal structure that reflects any impinging IR radiation (the relatively thick top metal layer acts as a mirror). Source and drain contacts are defined in the top metal layer of the head of the second cantilever and are electrically connected to the respective terminals on the substrate through the legs of the second cantilever structure. The head of the first cantilever carries the electrically floating metal tip (top contacting metal, or contact element). The first cantilever head is composed of a metal-insulator-metal structure in which the top metal layer is patterned to form an array of plasmonic nanostructures that enable strong absorption of IR radiation in the sub-wavelength structure.

When an IR beam impinges on the device from the top, it is selectively absorbed by the plasmonic head of the first cantilever, leading to a large and fast temperature increase of the freestanding micromechanical structure (i.e., head and inner leg portions) up to the two thermal isolation regions, where the high thermal resistivity of the insulator material (e.g., SiO₂) links the inner and outer legs and prevents heat transfer to the outer legs and the substrate. Such an IR-induced temperature rise results in a downward bending of the first cantilever's thermally sensitive pair of bimaterial legs due to the in-plane thermal stress caused by the large difference in the thermal expansion coefficients of the two materials forming each leg (e.g., 2 μm thick SiO₂ as the insulating layer and 500 nm thick Al as the metallic layer). This thermally-induced bending translates into vertical displacement of the first cantilever head; thus, a detection signal is registered as an upward movement of the absorber head away from the substrate, which closes the switch contacts. On the other side, the first cantilever's outer compensating pair of bimaterial legs as well as the entire second cantilever do not experience any temperature variation upon exposure to IR radiation. Therefore, the air gap separating the bottom drain/source contacts patterned on the head of the second cantilever from the top metal tip on the head of the first cantilever is directly controlled by the impinging IR radiation through a plasmonically-enhanced thermomechanical coupling. When the power of the IR radiation exceeds the designed threshold, the switch is activated, and the top metal tip is brought into contact, shorting the source and drain contacts allowing current to flow from the system battery to the load. The detection threshold for IR radiation can be designed, for example, over the range of about 5 nW to about 100 nW or higher. Despite the intrinsically high sensitivity of the sensor to IR-induced heat, the structure is completely immune to ambient temperature changes; both the inner and outer pairs of the legs supporting the two cantilevers bend in the same direction, thus minimizing any ambient temperature induced motion of the cantilever heads. Similarly, any mechanical bending of the cantilever legs due to residual stresses associated with the fabrication process is also minimized. Any residual ambient temperature and/or stress-induced deflections of the two cantilevers are compensated by the symmetry of the structure; because both the cantilevers deflect in the same fashion, the designed gap dimension is preserved. The devices have a fast response time of <100 ms to close contacts after exposure to IR radiation, and are spectrally selective, with a full width at half maximum of <10%. Spectral selectivity can be established by design of the plasmonic absorber metasurface, using known methods.

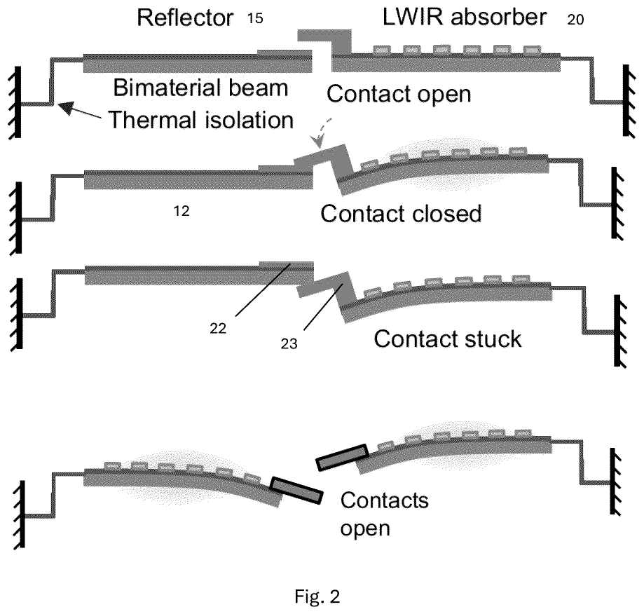

The working principle described above relies on delicate bi-material cantilevers to translate a small and localized temperature increase (induced by absorbed IR radiation) into a displacement that closes a sub-μm contact gap (FIGS. 1B-1C). To maximize the thermal sensitivity, long, thin beams connected to narrow thermal isolation links are preferred, which makes the device fairly “soft” in the z direction. On the other hand, an absorber with a certain minimum area is required for collecting the IR power from the target. Together, the absorber and the thermally-sensitive beams can be seen as a spring-mass system that is very sensitive to acceleration in the z direction. In principle, the symmetric design between the two sides of the ZIR sensor prevents false triggering when the device is exposed to common mode interferences from the environment, including temperature change, shock, and vibration. However, severe shock (i.e., contacts stuck open or closed, see FIG. 2) can still cause failure or damage (e.g., material rupture) to the device due to head design mismatch, second order effects, and excessive displacement. Similarly, if the device is exposed to an IR radiation as much as a few hundred times larger than the designed threshold, which is possible for real-world applications when a hot object is in close proximity to the sensor, then the contacts of the device can become stuck. This would be a major roadblock towards the commercialization of the sensors. The present technology has addressed these issues by introducing a maximum displacement limiter (MDL) structure, such as a mechanical stop or restraint, as part of the device. As used herein, the following terms are used synonymously: maximum displacement limiter (MDL), mechanical stop, stop, mechanical stopper, stopper, restraint, pillar, and pillar structure.

The second cantilever structure can include a reflector head, which functions to reflect electromagnetic radiation in a broadband fashion, including the selected band for detection by the absorber head. By including a thick layer of reflecting metal, the reflector head ensures that the second cantilever compensates for changes in temperature and balances out environmental changes detected in the first cantilever structure, thereby ensuring that the gap between the contacts remains constant in the situation where temperature fluctuations in the environment that are unrelated to the signal to be detected.

The substrate for the present devices can be composed of or contain silicon, silicon dioxide, or other nonconductive or semiconductive material. The substrate should be compatible with standard MEMS fabrication techniques.

The spectral band selected for detection can be any range of wavelength of electromagnetic radiation capable of plasmonic absorption by a MEMS device using a metasurface and providing sufficient energy to produced the conformation changes within the device to carry out movement of the contacts to close and/or open the switch. For example, the selected wavelength can be the infrared range of about 780 nm to about 1000 μm or any subset of this range, such as about 750 nm to about 100 μm, or from about 2.5 μm to about 17 μm, or about 30 μm to about 100 μm.

The bimaterial legs each comprise a stack of at least two materials having different thermal expansion coefficients. For example, the bimaterial legs can each comprise a bottom insulating layer (e.g., SiO₂) and a top metallic layer (e.g., Al).

The thermal isolation regions are thin links between the inner and outer biomaterial legs containing high thermal resistivity insulator material (e.g., SiO₂) which prevents heat transfer from the inner legs to the outer legs and the substrate.

The maximum deflection limiter (MDL) can be any structure that is fixed onto, attached to, or embedded or rooted in the substrate. It is a rigid, solid structure whose size, shape, and placement on the substrate are selected to provide resistance to aberrant motion of an absorber head or reflector head caused by mechanical shock encountered during commercial transportation, vandalism efforts, or input radiation of higher power than the designed dynamic range of the device. The MDL can be implemented during fabrication of an MP device using existing microfabrication techniques without any additional process development. The MDL is able to handle a shock even larger than the one defined in industrial standard tests for sensors, and functions properly when the device is exposed to an IR radiation hundreds or thousands of times larger than the designed triggering threshold. The new MP devices described herein represent an industrially-relevant solution to increase the device mechanical reliability and overall robustness but preserve all the existing design features for high thermal sensitivity and immunity to ambient temperature variation. In addition to offering greater mechanical stability and resistance to high input signal power, the present MDL structure also acts as a thermal dissipation path by which excessive heat can be diverted, thereby increasing the dynamic range of the sensor.

In order to effectively prevent stuck contacts, it may be effective to include more than just one or more MDLs under the absorber head. That is, performance may be improved by also providing one or more additional MDLs under the second or reflector head, so as to prevent its associated contact from moving out of normal operating position due to movement of the reflector head downward toward the substrate.

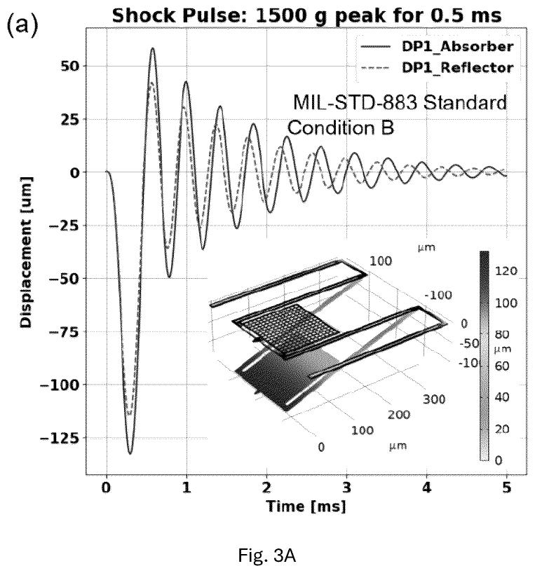

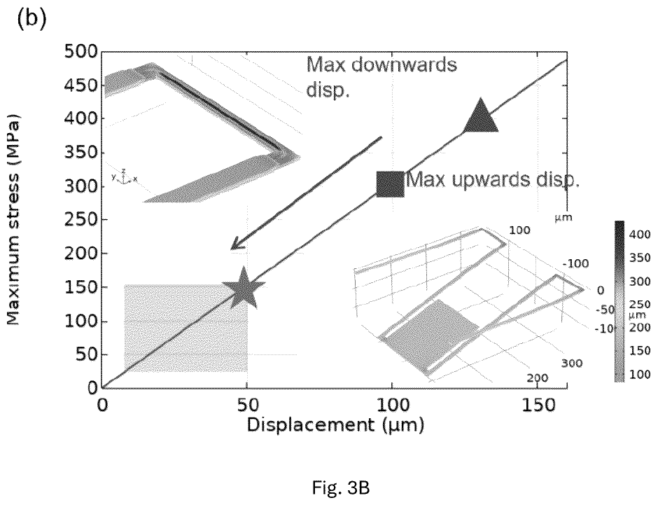

Although target applications of the present technology are generally stationary for installed sensors, unexpected shocks may result from suddenly applied forces or abrupt changes in motion produced by rough handling, transportation, vandalization, or misuse in field operation. Therefore, the mechanical reliability of the device ought to be carefully analyzed and optimized in order to meet at least the requirements for consumer electronics components. Integrated circuits and sensors for common commercial use are typically tested against MIL STD-883 standard Condition B (half sine shock load peaked at 1500 g with a pulse duration of 0.5 ms). FEM simulations of ZIR devices with previous designs show failure under such a condition due to the contact tip being flipped and stuck (FIG. 3A). At the same time, the maximum stress in the device under such conditions approaches the material fracture strength, which could cause permanent damage to the device (FIG. 3B). It's worth noting that large displacement leading to a flipped contact can also be caused by an overwhelming power of incident IR radiation, such as from a fire or soldering iron in close proximity to the sensor. Devices according to the present technology can withstand, without causing stuck contacts or other forms of temporary or permanent lack of responsiveness, incident radiation having a power of at least 100-fold, or at least 1000-fold, or at least 10000-fold, or even 100000-fold or greater compared with the designed threshold for activating the switch of the device. For example, a device designed to have a threshold for activation of 200 nW can withstand up to 1 milliwatt, or even 10 milliwatts of incident radiation in the selected spectral band without damage due to the presence of the pillar or MDL structures in the device.

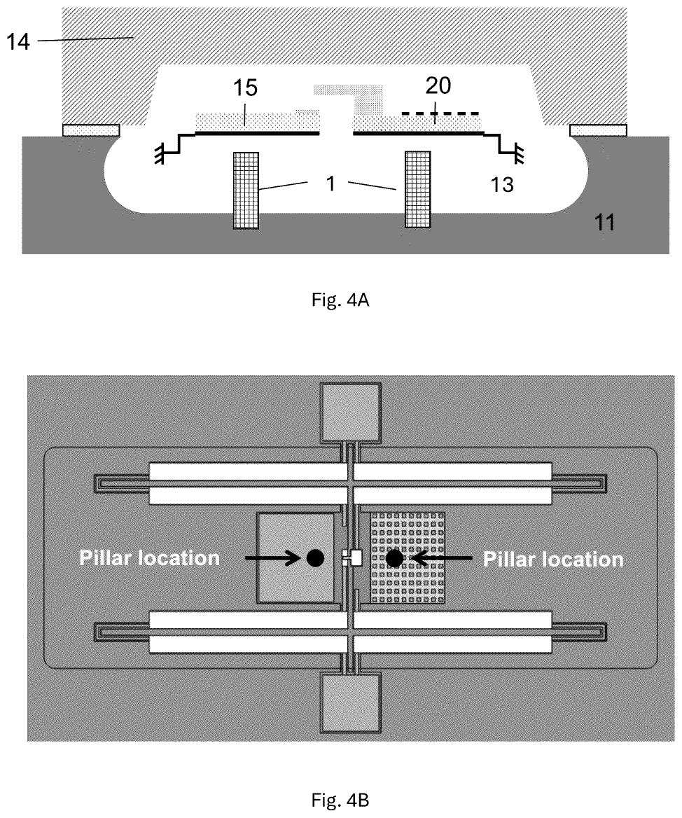

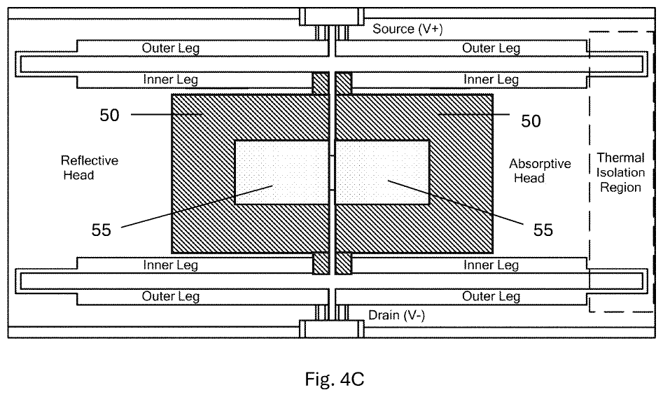

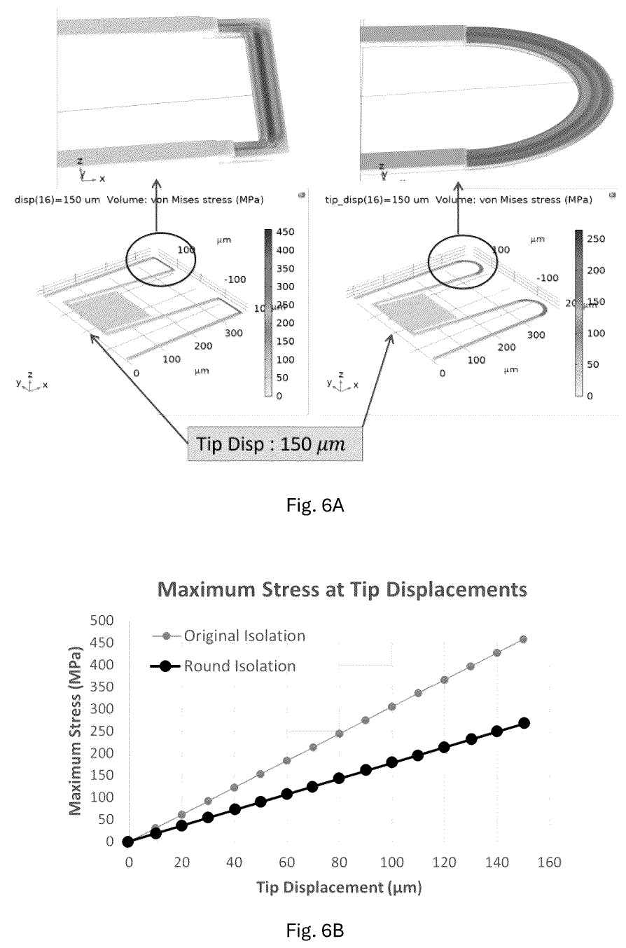

The MPs of the present technology have, compared to previous such devices, improved reliability and robustness produced by one or more of the following: 1) adding mechanical stoppers (also referred to herein as maximum displacement limiters or MDLs; see FIG. 4A, 001) onto the substrate (11) inside of the released cavity (13), the stoppers serving to limit the downwards displacement of both absorber and reflector heads (FIG. 4A, 4B); 2) optimizing the shape or profile of the thermal isolation links of the sensor device from 90-degree turns to a half-round shape to reduce stress accumulation (FIG. 6A); and 3) reducing the cavity depth in the lid wafer (14, used for wafer-level vacuum packaging) to limit the upwards displacement. Note that method 3) cannot be applied to the release cavity in the substrate due to the required undercut for the isotropic release and the required large room for the downwards bending of the bimorph during high temperature process such as wafer bonding and soldering.

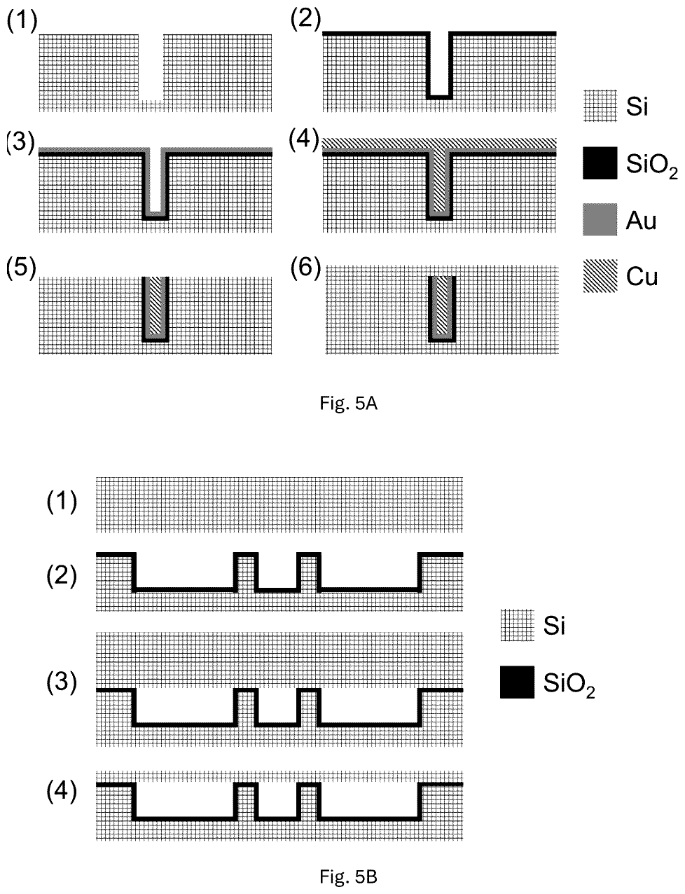

In an embodiment, the pillar-like stopper can be made of copper using the mature Through Silicon Via (TSV) process at a MEMS foundry (FIG. 5A). Furthermore, thanks to the high thermal conductivity of copper, a copper-based stopper also acts as a thermal dissipation path for excessive heat, hence increasing the dynamic range of the sensor.

The MDLs are preferably placed along the horizontal center line (x-axis) of the device (FIG. 4B). The exact location along the x-axis should be determined based on the maximum allowable downwards displacement for each head. Since the movement of the heads is rotational, and the distance between the top of the MDLs and the bottom of the heads is the same if two or more MDLs are used in a device, their location along the x-axis can be chosen as a factor to determine the maximum allowable downwards displacement. Further, the location of the MDL with respect to a head, or the maximum allowable rotation angle of the head, can be set independently for each side of the device, even if the distance between the MDL and the head is the same for both sides. The number of MDLs used for a device can vary from one to multiple based on the desired outcome of limiting head movement. The size of each MDL, including its diameter and height, can also be selected based on the desired mechanical and thermal properties of the pillar. An example of an MDL is a cylindrical structure having a diameter of about 25 μm and a height of about 250 μm. The height of the MDLs can be larger than the release depth of the cavity underneath the device; as a result, the MDLs will be securely rooted inside the Si substrate after release of the MP structure (as illustrated in FIG. 4A).

The fabrication of the MDLs can, for example, follow the mature process of through silicon vias (TSV) as illustrated in FIG. 5A. In an example of such a process, deep reactive-ion etching is first used to drill a hole in a Si subtract from the surface to define the dimensions of the pillar. Then a thin layer of SiO₂ is deposited as a liner on top of the Si surface using chemical vapor deposition, followed by deposition of a thin layer of gold on top of the SiO₂ as the seed layer for copper plating. Thick copper is then electroplated to fill up the hole. After that, chemical mechanical polishing (CMP) is used to remove the copper, gold, and SiO₂ layers on the top surface and planarize the surface to expose the copper via (i.e., pillar). Subsequently, amorphous silicon (a-Si) is deposited on the polished surface to define the gap between the pillar and the bottom of the heads of an MP that will be fabricated on top of the surface.

Placement of the MDLs is intended to limit the downwards displacement of the heads (e.g., due to shock or vibration), while not limiting the downwards displacement of the legs (due to thermal expansion). Each MDL should be placed in the area underneath the corresponding head, or where the head connects to the attached inner leg. Multiple MDLs optionally can be placed underneath one head to achieve a better stopping effect or stopping at different displacements for different areas of the head. FIG. 4C shows preferred zones for placement of MDLs to promote optimal safeguarding of the absorber head and reflector head against mechanical shocks and signals out of the designed dynamic range of the device. Placement of two or more MDLs per head is preferred to be in peripheral zone 50 in order to provide excellent mechanical stopping effect of the heads. An alternative strategy can be to place a single MDL beneath each head, in which case the MDL should be placed in central zone 55, which is close to the horizontal and vertical center lines through the device.

In order to stop excessive downwards displacement of the heads while not interfering with the normal operation of the switch, the top of the MDL needs to maintain a gap between the top of the MDL and the bottom of the head. This gap can be, for example, in the range from 1 to about 150 μm, and preferably the gap is about 10 μm. The gap is preferably filled with air or vacuum, and contains no solid or liquid material. The MDL needs to be strong enough to act as a mechanical stopper, and therefore the diameter or cross-sectional area of the MDL should be sufficiently large to provide adequate rigidity. The size and shape of the MDL can depend on the materials it contains and their mechanical properties. The MDL diameter, cross-sectional area, or contact area where the MDL contacts the head to prevent excessive deflection, should not be bigger than the head area. For example, the MDL can have a diameter or cross-sectional greatest dimension or extent, preferably at the contact area with the head, in the range from about 10 μm to about 150 μm. For the case of multiple MDLs per head, the diameter or largest cross-sectional extent of each can be as small as 1 μm. The MDL can have any shape consistent with its function. For example, the MDL can have the shape of a cylinder or pillar, such as a right circular cylinder, an oblique cylinder, an elliptic cylinder, a capsule, a truncated capsule, a hyperbolic cylinder, or a parabolic cylinder. The MDL also can be a pyramid-like structure, such as a truncated pyramid (a frustrum of a pyramid) having any geometric shape, or an irregular shape, as its base. The MDL also can be a column or have a columnar shape, such as a rectangular or square column, or a column having any geometric shape, or an irregular shape, as its cross-sectional form. The MDL also can be a cuboid structure. The height of the MDL needs to be sufficiently long to root inside or connect to the remaining substrate after release while maintaining the required gap above. For example, when using a typical Si wafer as the substrate, the height of an MDL structure can be from about 10 μm to about 750 μm.

The MDL can be made of any solid material commonly used in microfabrication, or any combination thereof, including any desired thin film coatings. Preferred materials include silicon (for simple fabrication) and metals (including copper, gold, aluminum, platinum, silver, and tungsten) due to their higher thermal conductivity which let the pillar not only serve as a mechanical stopper but also a heat dissipation channel to the substrate. Coating is optional based on the selected microfabrication process. The coating material can be, for example, silicon dioxide, or any metal oxide used for promoting adhesion or electroplating. More than 1 layer of coating can be used based on the selected microfabrication process.

A device of the present technology has many possible uses. For example, it can be used as an unattended ground sensor that lasts for years and identified remote threats, such as presence of humans or animals, vehicular pollution, gunfire, explosion, natural fire, or any unexpected or unusual source of heat. It can be used as a miniaturized and zero-power combat identification trigger that remains covert unless illuminated by a friendly laser target designator. It can be used in wearable sensors that constantly monitor radiation levels of surroundings with zero-power consumption. A device of the technology also can be employed as a zero-power sensor node for the Internet of Things. A device or system can incorporate one or more switches of the present technology and can be used as, for example, an exhaust gas detector, a living organism detector, a proximity sensor for a heat source or an organism, an infrared detector, a visible light detector, a color sensor, a spectrograph, or an electro-optical switch.

In one embodiment of the device, an array of ZIRs are connected to implement a passive logic circuit. The device separates the system battery from an output load capacitor. Each device, according to its design, is selectively triggered by impinging radiation at a specific spectral wavelength. When the anticipated spectral signature is absent, at ambient background conditions, the system battery is disconnected from the output load, resulting in a digital output voltage of <10 mV. However, when exposed to the target spectral signature (e.g., the exhaust plume of a vehicle), a specific combination of ZIRs is activated, according to the implemented logic, connecting the system battery to the load capacitor, which is charged to a voltage value of >1V, indicating positive detection of the target.

An infrared digitizer device exploits the energy in heated gas molecules to detect and discriminate the presence of an exhaust plume of interest, or other source of IR emission, while rejecting background interference from other warm objects, without the need of any additional power source, which directly translates into near-zero standby power consumption.

### EXAMPLES

### Example 1: Through Silicon Via Fabrication Process for Making a Maximum Displacement Limiter

A Through Silicon Via (TSV) process is used to make a pillar on a silicon substrate using electroplated metal. The fabrication process of the pillars follows the TSV technology available at most MEMS foundries, which is illustrated in FIG. 5A. First, deep reactive-ion etching is used to drill a hole in a silicon substrate from the surface to define the dimensions of the pillar. Then, a thin layer of SiO₂ is deposited as a liner on top of the Si surface using chemical vapor deposition, followed by a thin layer of gold deposited on top of the SiO₂ as the seed layer for copper plating. Thick copper is then electroplated to fill up the hole. After that, chemical mechanical polishing (CMP) is performed to remove the copper, gold, and SiO₂ layers on the top surface and to planarize the surface to expose the copper via (used here as a MDL in form of a pillar or having another form). Subsequently, amorphous silicon (a-Si) is deposited on the polished surface to define the gap between the pillar and the bottom of the heads of an MP that later will be fabricated on top of the a-Si surface.

### Example 2: Bulk Machining Fabrication Process for Making a Maximum Displacement Limiter

Bulk machining techniques are used to shape pillars out of a silicon substrate and then bond another Si wafer on top for the subsequent device fabrication without refilling the cavity. This fabrication process is a bit simpler than that described in Example 1, but the material choice for the pillar is limited to Si. The process starts with using dry etch to define the shape/size of the pillars as well as the device release cavity. After that, SiO₂ is grown on the etched surface using thermal oxidation. Then, a second Si wafer is bonded to the top surface of the etched wafer using fusion bonding. The second wafer is then thinned down using grinding and polishing to define the gap between the pillar and the bottom of the heads of a ZIR switch device. Device fabrication is continued on the thinned Si wafer. The final device is then released from the thinned Si wafer, and its release is made easier because the release cavity is largely pre-defined when creating the pillars. Only a thin layer of Si needs to be selectively etched to completely release the device.

As used herein, “consisting essentially of” allows the inclusion of materials or steps that do not materially affect the basic and novel characteristics of the claim. Any recitation herein of the term “comprising”, such as in a claim or in a description of components of a composition or in a description of elements of a device, can be replaced as an alternative with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein. Any examples of descriptions of structures, components, materials, or method steps designed to perform a function or achieve a result are not intended to invoke “means plus function” or “step plus function” claim construction; the examples are merely provided to help illustrate the claimed subject matter using certain nonlimiting embodiments.

What is claimed is:

1. A microelectromechanical photoswitch comprising:
a substrate;
a first electrical contact;
a maximum deflection limiter (MDL) attached to the surface of the substrate;
a first cantilever attached to the substrate, the first cantilever comprising:
an absorber head, wherein the absorber head comprises a second electrical contact disposed at a free end of the cantilever for movement into and out of electrical connection with the first electrical contact, and wherein the absorber head further comprises a plasmonic absorber that absorbs electromagnetic radiation within a spectral band selected for detection, the absorption of such electromagnetic radiation causing the second contact element to move toward the first contact element;
an inner pair of temperature-sensitive bimaterial legs, and an outer pair of temperature-sensitive bimaterial legs, the inner pair of legs attached to opposite sides of the absorber head, the outer pair of legs attached to the surface of the substrate and disposed adjacent to the inner pair of legs forming two sets of inner and outer legs, the two sets of legs disposed symmetrically on opposite sides of the absorber head; and
a first thermal isolation region connecting the inner and outer legs of the first set of legs, and a second thermal isolation region connecting the inner and outer legs of the second set of legs;
wherein the first and second electrical contacts are separated by a gap when the photoswitch is in an open state;
wherein absorption of said electromagnetic radiation by the plasmonic absorber causes the first electrical contact element and the second electrical contact element to form an electrical connection, thereby placing the photoswitch into a closed state; and
wherein the MDL is configured to limit movement of the absorber head in direction of the substrate, thereby inhibiting formation of a stuck state of the photosensor.

2. The microelectromechanical photoswitch of claim 1, further comprising:
a second cantilever disposed on the substrate adjacent to the first cantilever and with mirror symmetry to the first cantilever, the second cantilever comprising:
a second head;
an inner pair of temperature-sensitive bimaterial legs, and an outer pair of temperature-sensitive bimaterial legs, the inner pair of legs attached to opposite sides of the second head, the outer pair of legs attached to the surface of the substrate and disposed adjacent to the inner pair of legs forming first and second sets of inner and outer legs, the first and second sets of legs disposed symmetrically on opposite sides of the second head; and
a first thermal isolation region connecting the inner and outer legs of the first set of legs, and a second thermal isolation region connecting the inner and outer legs of the second set of legs; and
an additional MDL, wherein the additional MDL is configured to limit movement of the second head in direction of the substrate.

3. The microelectromechanical photoswitch of claim 2, wherein the second head reflects electromagnetic radiation over a bandwidth that includes the selected spectral band and does not absorb electromagnetic radiation.

4. The microelectromechanical photoswitch of claim 1, wherein the MDL is attached to the surface of the substrate below the absorber head.

5. The microelectromechanical photoswitch of claim 4, wherein the MDL is attached to the surface of the substrate below a perimeter zone of the absorber head.

6. The microelectromechanical photoswitch of claim 1, comprising two or more MDLs, each attached to the surface of the substrate below the absorber head.

7. The microelectromechanical photoswitch of claim 2, wherein the additional MDL is attached to the surface of the substrate below the second head.

8. The microelectromechanical photoswitch of claim 2, wherein the additional MDL is attached to the surface of the substrate below a perimeter zone of the second head.

9. The microelectromechanical photoswitch of claim 2, comprising two or more additional MDLs, each attached to the surface of the substrate below the second head.

10. The microelectromechanical photoswitch of claim 1, wherein the MDL has a form selected from the group consisting of columns having any geometrical shape in cross-section, truncated pyramids, and cuboids.

11. The microelectromechanical photoswitch of claim 1, wherein the MDL has a cross-sectional diameter from about 1 μm to about 250 μm.

12. The microelectromechanical photoswitch of claim 1, wherein the MDL has a height above the substrate from about 10 μm to about 750 μm.

13. The microelectromechanical photoswitch of claim 1, comprising a gap between an upper surface of the MDL and a lower surface of the absorber head, the gap having a size from about 1 μm to about 150 μm in a resting state.

14. The microelectromechanical photoswitch of claim 1, wherein the MDL comprises a material selected from the group consisting of silicon, silicon dioxide, copper, gold, aluminum, platinum, silver, tungsten, and metal oxides.

15. The microelectromechanical photoswitch of claim 1, wherein the MDL is fabricated by a process comprising through silicon via fabrication.

16. The microelectromechanical photoswitch of claim 1, wherein the MDL is fabricated by a process comprising bulk machining of the substrate.

17. The microelectromechanical photoswitch of claim 1, wherein the photoswitch has an increased maximum power absorption of electromagnetic radiation compared to a similar device lacking the MDL.

18. The microelectromechanical photoswitch of claim 1, wherein the photoswitch has a reduced likelihood of developing stuck contacts compared to a similar device lacking the MDL.

19. The microelectromechanical photoswitch of claim 18, wherein the photoswitch has a reduced likelihood of developing stuck contacts from mechanical shock or exposure to electromagnetic radiation of excessive power compared to a similar device lacking the MDL.

20. The microelectromechanical photoswitch of claim 1, where in the selected spectral band is an infrared radiation.

21. The microelectromechanical photoswitch of claim 1, which is vacuum packaged.

22. The microelectromechanical photoswitch of claim 1, wherein the MDL comprises a heat conducting material.

23. An electronic circuit comprising the microelectromechanical photoswitch of claim 1, a battery, and a transmitter or alarm.

24. An electrical device or a system comprising one or more microelectromechanical photoswitches of claim 1.
